(19) United States
(12) Patent Application Publication
(10) Pub. No.: US 2009/0079592 A1
(43) Pub. Date: Mar. 26, 2009

(54) Electrical navigation device

(75) Inventors: Chien-Yu Hsu, Kwei-Shan Hsiang (TW); Hui-Hsueh Chiang, Kwei-Shan Hsiang (TW)

Correspondence Address: Joe McKinney Muncy, PO Box 1364, Fairfax, VA, 22038-1364, US

(73) Assignee: SPEED TECH CORP.

(21) Appl. No.: 12/068,506

(22) Filed: Feb. 7, 2008

(30) Foreign Application Priority Data
Sep. 20, 2007 (TW) 96215845

(51) Int. Cl. H03K 17/94

(52) U.S. Cl. 341/20

(57) ABSTRACT

This present invention is an electrical navigation device, comprising a base, two encoders and two terminal sets. The base, comprising a rolling rod, is set on a circuit board, the two encoders are set on both sides of the rolling rod of the base, and the two encoders stretch to each other plurality of brushes. The two terminal sets are set on the circuit board corresponding to the two encoders respectively, and each terminal set is composed of two terminals which is not connected to each other. Each of the two terminal sets comprising a terminal which being in normal touch with the corresponding encoder respectively, and the other terminal can being in occasional touch with the corresponding encoder respectively when the rolling rod of the base is rolling.

### RELATED APPLICATIONS

This application claims priority to Taiwan Application Serial Number 96215845, filed Sep. 20, 2007, which is herein incorporated by reference.

1. Field of Invention

The present invention relates to an electrical navigation device. More particularly, the present invention relates to an electrical navigation device with a low profile.

2. Description of Related Art

Electrical navigation devices are widely applied for an input device or a control device, such as the electrical navigation device in portable telecommunications. In prior art, the terminal of the electrical navigation device should be welded onto the circuit board in the soldering process, for electrical connection between the electrical navigation device and the circuit board. Refer to FIG. 1. FIG. 1 illustrates an electrical navigation device of the Patent No. M289230 of the Republic of China comprises a navigation body 10, a base 20, and terminal sets 30. The navigation body 10 is assembled on the base 20. The encoder 12 and the wheel 13 are disposed on the frame 14 corresponding to the oscillating shaft 11. The terminal set 30 is inserted into the base 20 toward the encoder 12 and contacts the encoder 12. The oscillating shaft 11 with the wheel 13 can be assembled in the base 20 through the Reflow Soldering process. Due to the first terminal 31 of the terminal set 30 carried on the second terminal 32, and the first terminal 31 contacting the inner surface of the encoder 12, plus the height of the wheel 13 enclosing the encoder 12, the product volume is limitedly diminished.

### SUMMARY

For this reason, the present invention provides an electrical navigation device with a low profile. The electrical navigation device of the invention comprises a base, a first encoder, a second encoder, a first set of terminals and a second set of terminals. Wherein the base, having a rolling rod, is disposed on a circuit board, the two encoders are electric conducting sleeves as encoding components, respectively capping onto both ends of the rolling rod, and the two terminal sets, each of which composes of two terminals without any connection between each other, are disposed on the circuit board.

By the arrangement of the invention that encoders are capped onto both ends of the rolling rod, the profile of the electrical navigation device is lowered consequently.

### BRIEF DESCRIPTION OF THE DRAWINGS

The invention can be more fully understood by reading the following detailed description of the embodiment, with reference made to the accompanying drawings as follows:

FIG. 1 illustrates a navigation device in prior art.

FIGS. 2A, 2B, and 2C illustrate components of the preferred embodiment of the electrical navigation device of this invention.

FIG. 3 is the side perspective drawing of the preferred embodiment of the electrical navigation device of this invention.

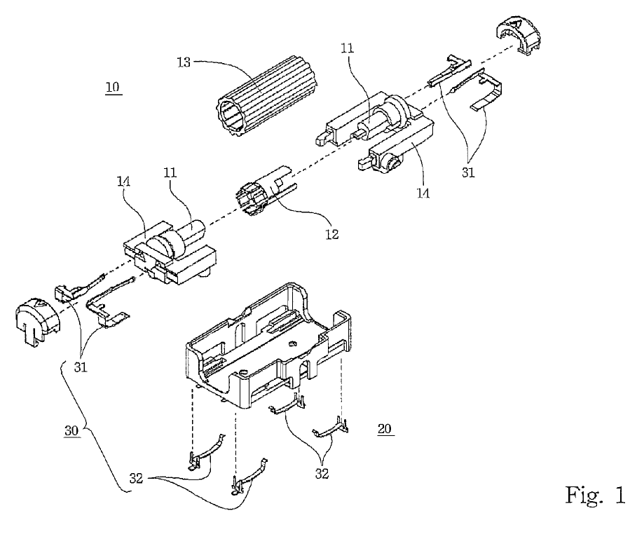

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

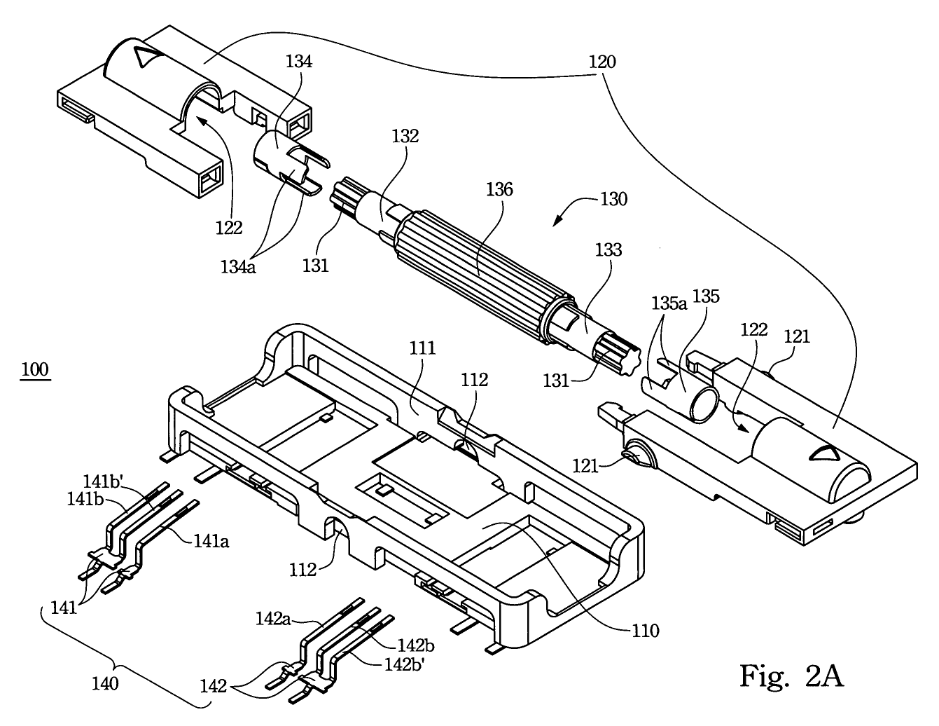

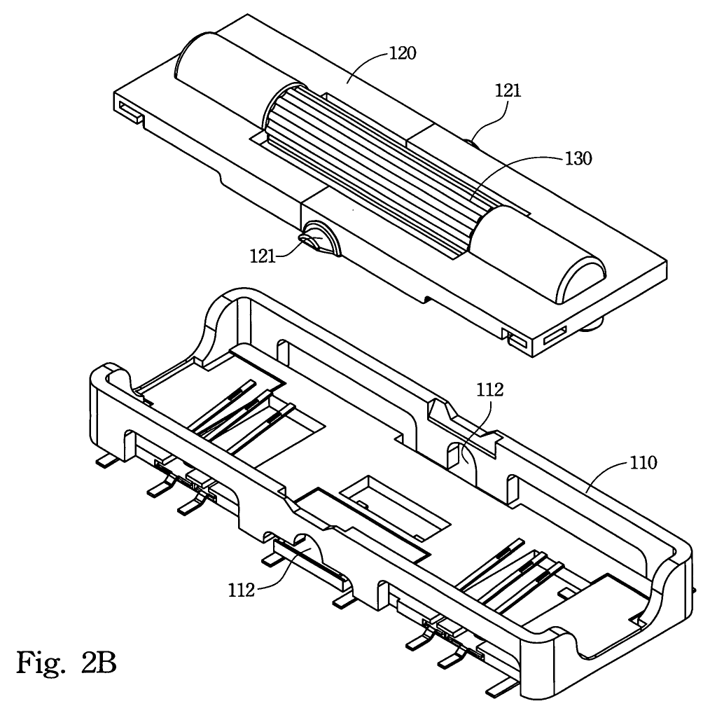

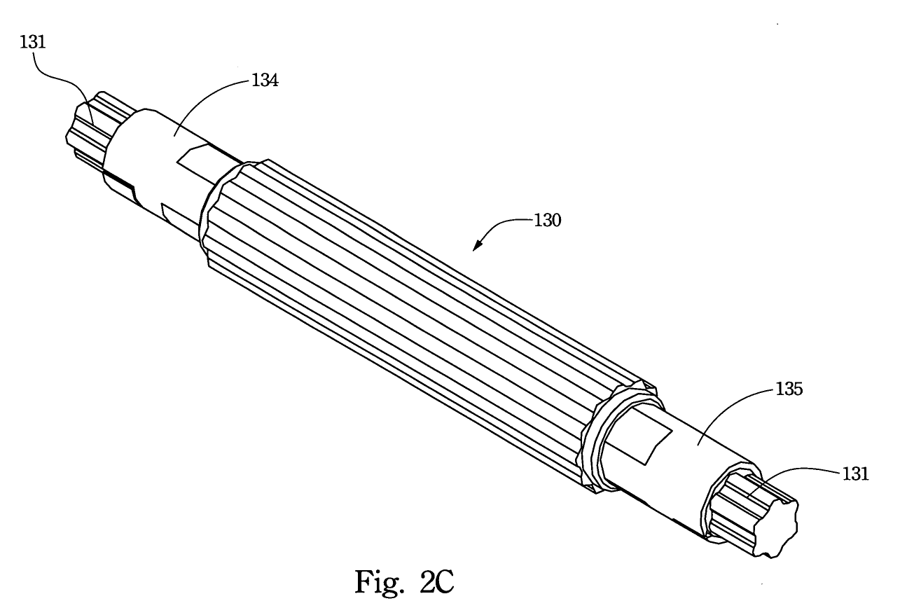

Refer to FIGS. 2A, 2B, and 2C. The preferred embodiment of the electrical navigation device 100 comprises a base 110, a frame 120, a rolling rod 130, two encoders 134, 135, and a terminal set 140. In general, the base 110, the frame 120, and the rolling rod 130 are made of insulating materials such as plastic. And, the two encoders 134, 135 as sleeve-shaped encoding components and the terminal set 140 are all made of electrically conductive materials such as metal.

The base 110, the carrying base of the electrical navigation device 100, attaches the electrical navigation device 100 on a circuit board (not shown). In the preferred embodiment of the invention, the base 110 is, for instance, a carrying box having at least two sidewalls 111. Each sidewall 111 of the base 110 has a trough 112. Each side of the frame 120 extends an oscillating shaft 121, so that two oscillating shafts 121 are pivoting to the corresponding troughs 112 on the base 110 respectively. And a pair of revolving apertures 122 is disposed on the frame 120 for pivoting the rolling rod 130. Wherein the openings of the opposing troughs 112 are aligned in a line, which is perpendicular to the disposed direction of the rolling rod 130. Thus a user is able to swing the rolling rod 130 on the base 110 within a limited range as a seesaw by pushing both portions of the rolling rod 130 against the center point of two oscillating shafts 121. In addition, the pair of the revolving apertures 122 is aligned in another line, which is parallel to the disposed direction of the rolling rod 130. Thus a user is able to revolve the rolling rod 130 forwards or backwards by pushing the rolling rod 130 turning in the revolving apertures 122. Thus the electrical navigation device 100 of the preferred embodiment is able to be conducted to revolve forwards or backwards, and to swing leftwards or rightwards.

The central portion of the rolling rod 130 covers a rolling cylinder 136 for turning the rolling rod 130. Moreover, stripe veins are designed on the outer surface of the rolling cylinder 136 for slippery proof and touch sense. In addition, on both ends of the rolling rod 130 are ratchet wheels 131, respectively pivoted into the revolving apertures 122 on the frame 120.

The first encoder rabbet 132 and the second encoder rabbet 133 are disposed on both sides of the rolling rod 130, wherein the first encoder rabbet 132 and the second encoder rabbet 133 both have plural bulges arranged around the surface of the rolling rod 130 in different aspects toward each other. More specifically, three arranging orderly bulges of the first encoder rabbet 132 on the rolling rod 130 periphery are disposed in different projection aspects, e.g. being hardly overlapped or staggered, toward those three bulges of the second encoder rabbet 133. Nevertheless, the staggering first encoder rabbet 132 for placing the first encoder 134 and the staggering second encoder rabbet 133 for placing the second encoder 135 are arranged in advance when manufacturing the rolling rod 130. Therefore, electric brushes 134a of the first encoder 134, assembled among the first encoder rabbet 132 bulges, are staggered to the electric brushes 135a of the second encoder 135, assembled among the second encoder rabbet 133 bulges. The different aspects between the electric brushes 134a of the first encoder 134 and the electric brushes 135a of the second encoder 135 are arranged when manufacturing the rolling rod 130 for producing a specific phase difference.

The terminal sets 140, having a first terminal set 141 and a second terminal set 142, are disposed symmetrically to the oscillating shafts 121 in the bottom section of the base 110. More specifically, the first terminal set 141 and the second terminal set 142, separated by the oscillating shafts 121, are disposed correspondingly to the first encoder 134 and the second encoder 135 horizontally, and are lied in between the base 110 carriage surface and the frame 120 bottom vertically. The first terminal set 141 has the first terminal 141a and the second terminal 141b and the second terminal set 142 has the third terminal 142a and the forth terminal 142b, wherein the terminals all extend into the base 110. Therefore, the second terminal 141b contacts the main body of the first encoder 134 all the time, and the first terminal 141a alternately contacts the brushes 134a of the first encoder 134 when the rolling rod 130 revolves. As well as the forth terminal 142b contacts the main body of the second encoder 135, and the third terminal 142a alternately contacts the brushes 135a of the second encoder 135 when the rolling rod 130 revolves. Because of the staggered positions of the brushes 134a of the first encoder 134 and the brushes 135a of the second encoder 135 assembled on the rolling rod 130, the first encoder brushes 134a and the second encoder brushes 135a respectively contact the first terminal 141a and the third terminal 142a in sequence while the rolling rod 130 is revolving. Therefore, it is possible to induce the specified phase difference for the distinct operation signal with different contacting time of the electric brushes.

The second terminal 141b of the first terminal set 141 has a cantilever 141b′ and the forth terminal 142b of the second terminal set 142 also has a cantilever 142b′, and the cantilevers 141b′ and 142b′ are respectively extending toward the ratchet wheels 131 on both ends of the rolling rod 130, for improving the user's hand feels of turning the rolling rod 130 as turning a ratchet wheel.

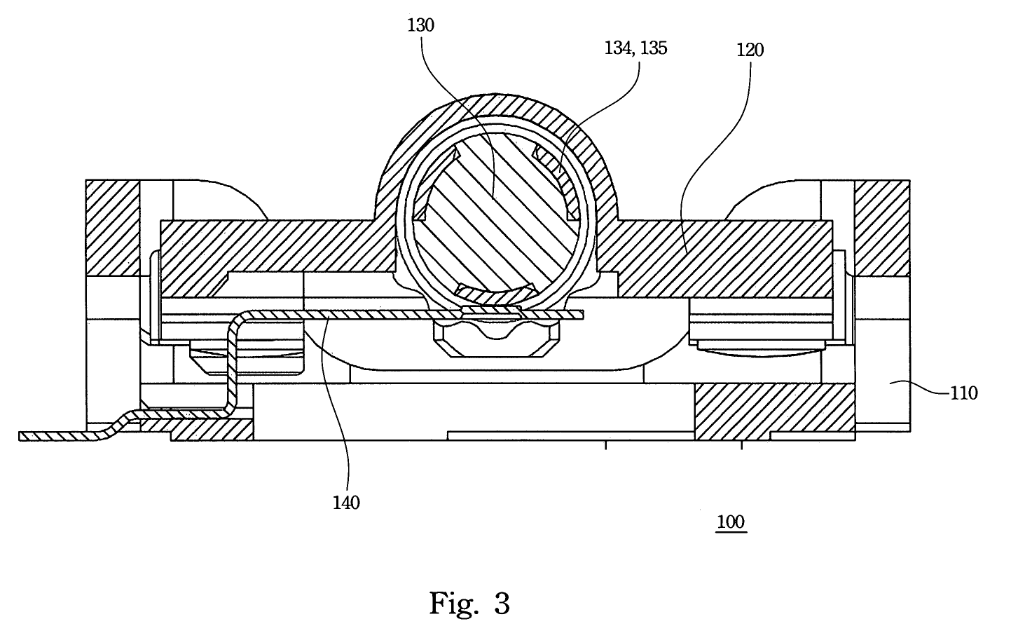

Refer to FIG. 3, the side perspective drawing of the preferred embodiment of the electrical navigation device of this invention. For the arrangement of the rolling rod 130 pivoting on the frame 120 and assembled on the base 110 of the electrical navigation device 100 of the invention, the encoders 134 and 135 are able to be assembled on the both sides of the rolling rod 130. And it is possible to induce the phase difference of electric signals by the first terminal set 141 and the second terminal set 142 contacting the encoders 134 and 135, due to the staggered aspects between the first encoder brushes 134a and the second encoder brushes 135a. Wherein the terminal sets 140 can also be arranged in the base 110 for the contact between the terminals and the brushes as other embodiments, but should not be limited to the description of the embodiments contained herein.

Therefore the volume of the rolling rod of the electrical navigation device of the invention potentially diminishes, for manufacturing the electrical navigation device with low profile. Furthermore, dimensions of the electrical navigation device by plastic injection molding are more accurate than by assembling. The different aspects between the electric brushes of the encoders assembled in the encoder rabbets are arranged when manufacturing the rolling rod, for inducing the specific phase difference. And the terminal sets are also easy to be assembled onto the electrical navigation device of the invention. More specifically, the staggered aspects between the encoders are determined when assembling the encoders on both sides of the rolling rod in the base. So it is possible to design the electrical navigation device of accurate phase difference with the aspects of simple structure and easy assembly.

According to the disclosure of the above-mentioned preferred embodiments, the base 110 and the frame 120 are designed differentially, but should not be limited to the description of the embodiments contained herein. It will be apparent to those skilled in the art to unify the base 110 and the frame 120 in one body or one element. Also, it will be apparent to unify the rolling rod 130 and the rolling cylinder 136 in one body or one element, and only to assemble the rolling cylinder 136 on the base 110.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electrical navigation device, comprising:
a base, disposed on a circuit board and having a rolling rod pivoted to the base;
a first encoder and a second encoder, being sleeve-shaped encoding components made of conductive materials, wherein the two encoders, which have a plurality of electric brushes extending in different aspects toward each other, respectively cap onto two opposite ends of the rolling rod; and
a first terminal set and a second terminal set, disposed on the circuit board respectively corresponding to the first encoder and the second encoder, wherein the first terminal set and the second terminal set are both composed of two terminals electrically insulated from each other;
wherein each of the two terminal sets has one terminal in contact with the encoder all the time, and the other terminal alternatively contacts the brushes of the first encoder, the second encoder and the rolling rod while the rolling rod revolves.

2. The electrical navigation device of claim 1, wherein two ends of the rolling rod have plural rabbets for placing the first encoder brushes and the second encoder brushes.

3. The electrical navigation device of claim 1, wherein the first encoder and the second encoder capped on the rolling rod potentially induce phase differences by contacting the terminals when the rolling rod revolves

4. The electrical navigation device of claim 1, wherein the base has a separable frame with oscillating shafts, and the base has troughs corresponding to the oscillating shafts for supporting the frame oscillating.

5. The electrical navigation device of claim 1, wherein both ends of the rolling rod respectively have ratchet wheels, and the two terminal sets in contact with the two encoders extends cantilevers respectively toward the ratchet wheel.
